(19) United States
(12) Patent Application Publication
(10) Pub. No.: US 2008/0203909 A1
(43) Pub. Date: Aug. 28, 2008

(54) Organic electroluminescence display device

(75) Inventor: Hitoshi Azuma, Yokohama (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 12/071,023

(22) Filed: Feb. 14, 2008

(30) Foreign Application Priority Data
Feb. 28, 2007 (JP) 2007-049651

(51) Int. Cl. H01L 51/54

(52) U.S. Cl. 313/504

(57) ABSTRACT

There is provided an organic electroluminescence display device with sufficient sealability that reduces discharge of gas and moisture infiltration into sealed space. An organic EL display device structured to coat the surface of a spacer fixed to the inner surface of a sealing substrate and a bonded surface of the side wall to a sealing member with an inorganic insulation film.

### CLAIM OF PRIORITY

The present application claims priority from Japanese Application JP 2007-049651 filed on Feb. 28, 2007, the content of which is hereby incorporated by reference into this application.

### BACKGROUND OF THE INVENTION

1. Field of the Invention

The present invention relates to an organic electroluminescence (EL) display device, and particularly to an organic EL display device provided with an organic EL display element which suppresses deterioration in an organic EL layer due to moisture for elongating the product lifetime and improving reliability.

2. Description of the Related Art

The display device of flat panel type, for example, the liquid crystal display device (LCD), the plasma display device (PDP), the field emission display (FED) device, and the organic EL display device (OLED) has been put into the practical use or in a developmental stage. Among all, the organic EL display device is regarded as being considerably promising to realize the thin and light display device of light-emitting type.

The organic EL display device includes two types, that is, the bottom emission type and the top emission type. In the organic EL display device of bottom emission type, the organic EL element is structured using the light-emitting mechanism formed by sequentially layering a lower electrode or a transparent electrode as one electrode (ITO), a multi-layer organic film which emits light upon application of the electric field (so called an organic light emitting layer), and an upper electrode or a metal electrode of reflex type as the other electrode on the main surface of an element substrate, preferably, a glass substrate to form the TFT substrate.

Plural the thus structured organic EL elements are arranged in the matrix state, the layer structure of which is coated with a sealing substrate or a sealing film so called the sealing can such that the peripheral portion between the element substrate and the sealing substrate is sealed with a sealing member to block the light-emitting structure from the outer atmosphere.

The electric field is then applied between the upper electrode as the metal electrode, that is, the anode and the lower electrode as the transparent electrode, that is, the cathode to allow the carrier (electron and hole) to be implanted into the organic multi-layer film to emit the light. The resultant light-emission is output to the outside from the element substrate side.

Meanwhile, in the organic EL display device of top emission type, the electric field is applied between the metal electrode of reflex type as one electrode and the transparent electrode as ITO, that is, the other electrode to allow the light emitting layer to emit light. The resultant light-emission is output from the other electrode side. In the organic EL display device of top emission type, the drive circuit on the insulation substrate may be used as the light emitting area. In the top emission type, the transparent plate, preferably the glass plate may be used as the structure corresponding to the sealing can used in the bottom emission type.

The above-structured organic EL display device, however, is liable to deteriorate the organic film which forms the light emitting layer due to moisture. For keeping the organic EL film from the moisture the desiccant (hydroscopic agent or drying agent) is provided inside the sealing can or the sealing film.

The aforementioned organic EL display device is structured to seal the sealing substrate 81 and the element substrate 82 with the sealing member 73 as shown in FIG. 9 as a sectional view schematically showing the organic EL display device in parallel with the light emitting direction.

Referring to FIG. 9, a recess portion 81a is formed in the inner surface of the sealing substrate 81 opposite an element substrate 82 to accommodate a desiccant component 84 to be fixed thereto. The desiccant component 84 is formed by combining a desiccant 86 as CaO (calcium oxide) or Sr (strontium) with a bond member 87 such as the adhesive compound. The desiccant 86 is fixed to the sealing substrate 81 with the bond member 87 so as to be kept.

Meanwhile, the light emitting element 85 is formed on the main surface of the element substrate 82, that is, the surface where the TFT element (not shown) is formed opposite the sealing substrate 81. The light emitting element 85 is formed by sequentially layering the transparent lower electrode 88, the organic multi-layer film 89 with the light emitting layer, and the upper electrode 90 formed of the metal film of reflex type on the element substrate 82.

The desiccant component 84 is installed in the aforementioned structure for preventing the performance deterioration of the organic multi-layer film 89 resulting from water absorption.

JP-A No. 2003-154227 discloses the technology which relates to the desiccant and a process for attachment thereof. JP-A No. 2004-265615 discloses the technology for preventing moisture infiltration and generation of bubble inside the sealing member. JP-A No. 2005-268062 discloses the technology for preventing uneven brightness in the large sized structure while easily reducing the production cost.

The aforementioned organic EL display device is structured to arrange the spacer between both the substrates. It has been proposed to form the spacer by sandblasting or etching the sealing substrate. However, the sandblasting provides the low density stepped portion owing to the problem in the working accuracy. Meanwhile, it may take a long time for forming the stepped portion through the etching, resulting in difficulties in formation of the long spacer.

The light emitting layer suffers from the gas discharged from the spacer to deteriorate the function. The function of the light emitting layer may also be deteriorated by the moisture infiltration through the bonded boundary between the sealing member and the substrate.

In the step for bonding the deflection plate to the outer surface of the substrate during manufacturing, the external pressure is applied to the substrate. As a result, the substrate is deformed to damage the light emitting element in contact with the desiccant, thus deteriorating its display property. The aforementioned risk may become more serious as the device size increases.

### SUMMARY OF THE INVENTION

It is an object of the present invention to provide the organic EL display device with long lifetime, high brightness and sharp contrast.

In the present invention, the spacer formed of the shaped resist resin coated to the sealing substrate or the spacer formed of the resin beads is fixed to the sealing substrate and the surface is coated with the inorganic insulation film.

In the present invention, the side wall is formed on the periphery of the sealing substrate, and the inorganic insulation film is interposed between the side wall and the sealing member.

In the present invention, the leading end of the spacer fixed to the sealing substrate is protruded toward the upper electrode from the surface of the desiccant opposite the upper electrode.

In the present invention, the spacer formed of the shaped resist resin coated to the sealing substrate or the spacer formed of the resin beads is fixed to the sealing substrate, and the surface is coated with the inorganic insulation film. This makes it possible to control the spacer arrangement considerably easily, and to obtain the spacer with the desired height or outer configuration within a short period of time.

As the spacer surface is coated with the inorganic insulation film, the gas is not discharged from the spacer to the sealed space. This makes it possible to provide the organic EL display device having the light emitting layer retained in good condition for an extended period of time with excellent display properties such as long lifetime, high brightness and sharp contrast.

As the side wall surface is coated with the inorganic insulation film, the moisture infiltration through the sealing member boundary may be blocked to retain the light emitting layer in good condition for an elongated period of time to provide the organic EL display device with excellent display properties such as long lifetime, high brightness and sharp contrast.

As the leading end of the spacer is protruded toward the upper electrode from the surface of the desiccant opposite the upper electrode, the upper electrode may be protected from damage caused by the desiccant, thus making sure to have excellent display properties.

The structure for protruding the leading end of the spacer from the desiccant surface enables the increase in the volume of the desiccant. This makes it possible to maintain the water absorption performance in the sealed space for an elongated period to provide the organic EL display device with excellent display properties such as long lifetime, high brightness, and sharp contrast. This also makes it possible to easily arrange the recess portion for accommodating the desiccant.

### BRIEF DESCRIPTION OF THE DRAWINGS

FIG. 1 is a sectional view schematically showing the structure of an organic EL display device according to an embodiment of the invention;

FIG. 2 is a sectional view taken along line A-A shown in FIG. 1;

FIG. 3 is a sectional view schematically showing a partially enlarged portion of FIG. 1;

FIG. 4 is a sectional view schematically showing a light emitting element shown in FIG. 1;

FIG. 5 is a sectional view schematically showing an organic EL layer shown in FIG. 1;

FIG. 6 is a sectional view schematically showing an organic EL display device according to another embodiment of the present invention;

FIGS. 7A and 7B schematically show organic EL display devices according to another embodiments of the present invention, wherein FIG. 7A illustrates a column-like spacer, and FIG. 7B illustrates a spherical spacer;

FIG. 8 is a sectional view schematically showing an organic EL display device according to another embodiment of the present invention; and

FIG. 9 is a sectional view schematically showing the generally employed organic EL display device.

### DETAILED DESCRIPTION

Embodiments of the present invention will be described referring to the drawings.

### First Embodiment

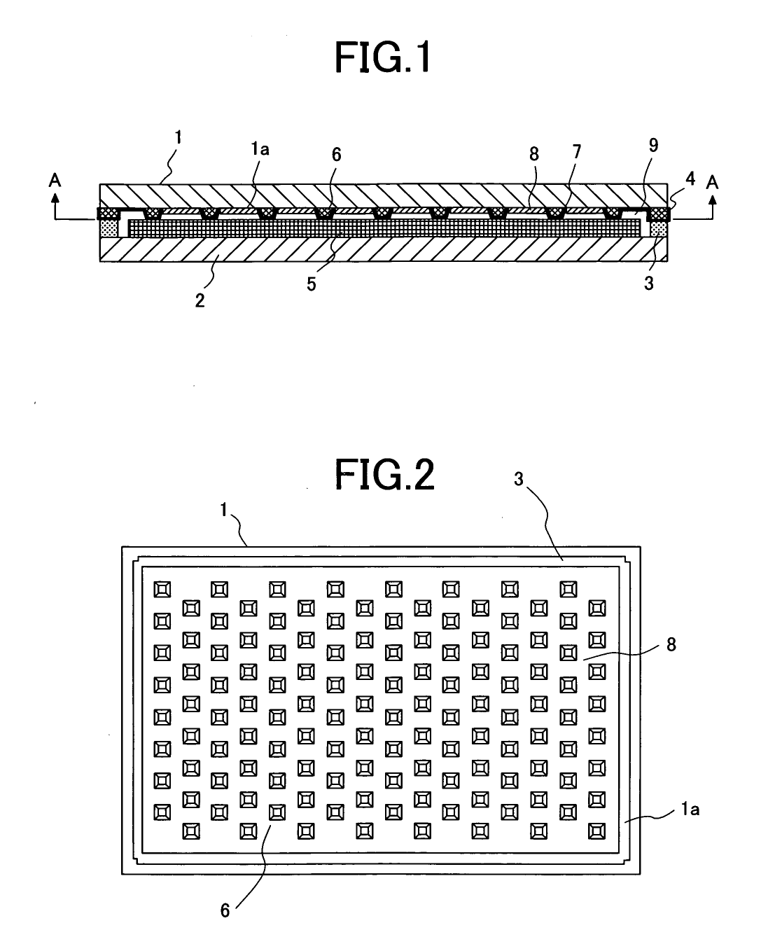

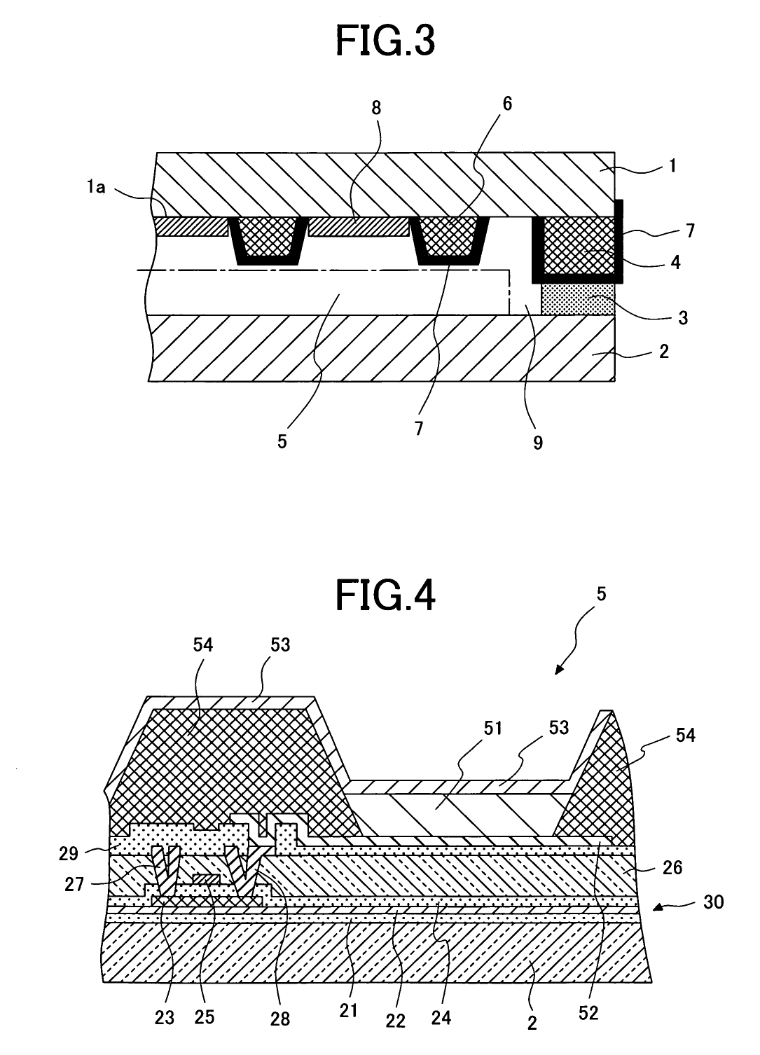

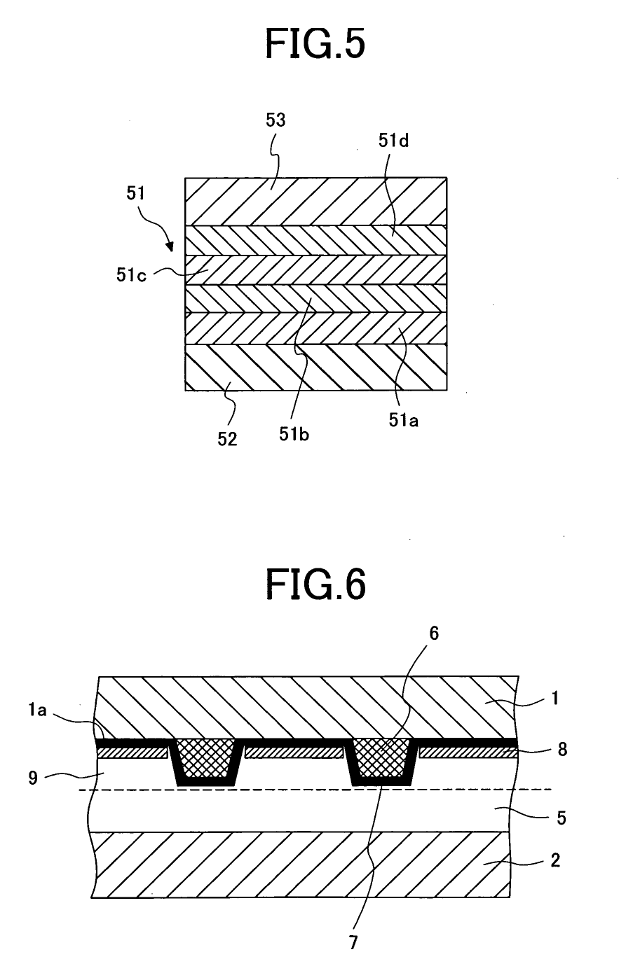

FIGS. 1 to 5 schematically show the structure of an organic EL display device according to an embodiment of the present invention. FIG. 1 is a sectional view in parallel with the light emitting direction. FIG. 2 is a sectional view taken along line A-A shown in FIG. 1. FIG. 3 is a partially enlarged sectional view of FIG. 1. FIG. 4 is a sectional view of the light emitting element. FIG. 5 is an enlarged sectional view of an organic EL layer.

FIGS. 1 to 5 show a sealing substrate 1, an element substrate 2, a sealing member 3, a side wall 4, a light emitting element 5, a spacer 6, an inorganic insulation film 7, a desiccant 8, and a sealed space 9. The sealing substrate 1 is formed of a glass material, for example, to be bonded to the element substrate 2 (described later) via the sealing member 3. The bonding is performed via the side wall 4 formed on the whole circumference of the periphery of the sealing substrate 1.

The element substrate 2 bonded to the side wall 4 is provided with the light emitting element 5 including a light emitting portion opposite the sealing substrate 1. Plural the spacers 6 opposite the light emitting element 5 are fixed to the sealing substrate 1 at the respective intervals. The spacer 6 is coated with the inorganic insulation film 7. The desiccant 8 is held on the sealing substrate 1 adjacent to the spacers 6 for accumulating water in the sealed space 9.

Meanwhile, one end of the side wall 4 is fixed to the sealing substrate 1, and the other end extending toward the element substrate 2 is coated with the inorganic insulation film 7. The side wall 4 is bonded to the sealing member 3 via the inorganic insulation film 7. Each of the side wall 4 and the spacer 6 formed of the resist resin is fixed to an inner surface 1a of the sealing substrate 1, each surface of which is coated with the inorganic insulation film 7.

The side wall 4 and the spacer 6 are formed by preliminarily applying the resist resin film to the inner surface 1a of the sealing substrate 1, and patterning the film into the desired configuration having the respective surfaces coated with the inorganic insulation film 7 for example, SiN film, SiON film, and SiO film. The inorganic insulation film 7 may be formed through such process as CVD or sputtering.

The desiccant 8 is disposed on the inner surface 1a as described above. The desiccant 8 is formed of the calcium oxide, strontium and the like. In the case of the top emission type, it is preferable to use the desiccant 8 with the transparent structure. Meanwhile, in the case of the bottom emission type, the desiccant 8 with either the transparent structure or translucent structure may be used.

The desiccant 8 is disposed over substantially the entire area of the inner surface 1a defined by the side wall 4 on the sealing substrate 1. The spacers 6 are fixed between the adjacent desiccants 8. The spacer 6 has its leading end protruding from the surface of the desiccant 8 toward the element substrate 2.

Meanwhile, the element substrate 2 is preferably a transparent glass substrate as the aforementioned TFT substrate 30, having a silicon nitride (SiN) film 21 and a silicon oxide (SiO₂) film 22 layered on the main surface as shown in FIG. 4. A semiconductor layer 23 is formed by patterning the semiconductor film on the switching element region of the silicon oxide SiO₂ film. A gate insulation film 24 is formed to coat the semiconductor layer 23, and a gate electrode 25 is patterned on the gate insulation film 24. An insulating flat film 26 is further formed to coat the surface of the aforementioned layered structure.

A wiring 27 denotes the wiring between switching elements as the drain electrode of the switching element (inter-switch wiring, signal wiring, drain wiring), and a wiring 28 denotes a source electrode and a wiring/shield member between the switching members (inter-switch wiring/shield member). Those wirings are connected to the semiconductor layer 23 through the contact hole which penetrates through the flat film 26 and the gate insulation film 24. An insulation film 29 is formed to coat the inter-switch wiring 27 and the inter-switch wiring/shield member 28. A flat lower electrode 52 connected to the inter-switch wiring/shield member 28 through the contact hole formed in the insulation film 29 extends toward the light emitting area. In the present structure, the lower electrode 52 serves as the cathode.

The light emitting element 5 has the lower electrode 52 disposed on the insulation film 29 of the element substrate 2 so as to connect the lower electrode 52 to the inter-switch wiring/shield member 28 via the contact hole formed in the insulation film 29. In the present structure, the lower electrode 52 serves as the cathode.

An organic EL layer 51, the upper electrode 53 with the reflecting property, and a protruding bank 54 are formed to be the lower electrode 52 such that the region defined by the bank 54 is formed as the light emitting area. The bank 54 is formed of the inorganic insulation material, for example, silicon oxide film and the silicon nitride film, and is configured to have an opening (bank opening) in the light emitting area. The bank 54 is configured to have a recess portion in the opening. The organic EL layer 51 is arranged both in X and Y directions in the matrix state.

FIG. 5 shows the organic EL layer 51 in detail. The organic EL layer 51 shown in FIG. 5 has an electron feed layer 51a in contact with the lower electrode 52, a light emitting layer 51b, a hole feed layer 51c, and a hole implantation layer 51d sequentially layered thereon. The upper electrode 53 is formed as the uppermost layer. It is possible to further interpose the inorganic insulation film 7 between the element substrate 2 and the sealing member 3.

The spacer 6 formed on the sealing substrate 1 abuts on the bank 54 formed on the element substrate 2. As the resist resin, a photosensitive acrylic resin may be employed. In the case where the photosensitive acrylic resin is used, the height of the spacer results in approximately several μms. In this case, the desiccant between the spacers may be formed as the coating type.

In the organic EL display device according to the first embodiment, the spacer and the side wall may be easily formed. As the surface of the structure is coated with the inorganic insulation film, discharge of gas to the sealed space may be suppressed, and the moisture infiltration through the bonded boundary may be prevented by the inorganic insulation film disposed with the sealing member. As the spacer is protruded from the desiccant surface, the light emitting display portion may be protected from the damage caused by the desiccant.

### Second Embodiment

FIG. 6 is a sectional view schematically showing the structure of an organic EL display device according to another embodiment of the present invention. The same elements as those in the aforementioned embodiment will be designated with the same reference numerals.

In the second embodiment, the inorganic insulation film 7 is applied to the inner surface 1a at the back side of the desiccant 8 in addition to the surface of the spacer 6 as shown in FIG. 6. The organic EL display device according to the second embodiment is structured to further suppress the discharge of gas.

### Third Embodiment

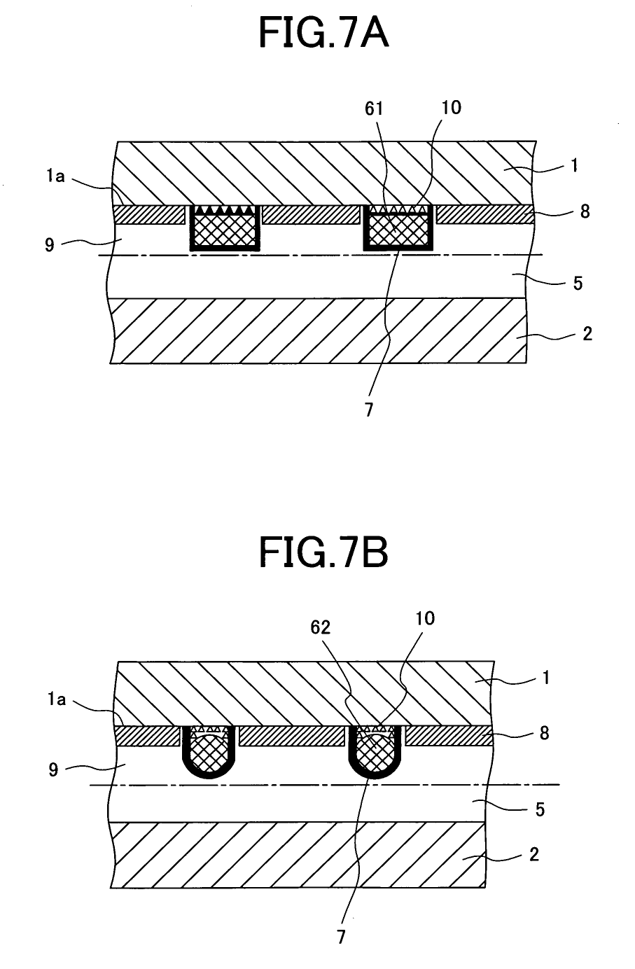

FIGS. 7A and 7B schematically show the structure of the organic EL display device according to another embodiment of the present invention. Specifically, FIG. 7A is a sectional view of the column-like spacer, and FIG. 7B is a sectional view of the spherical (bead-like) spacer. The same elements as those in the aforementioned embodiments will be designated with the same reference numerals.

In the embodiment shown in FIG. 7A, a column-like spacer 61 is derived by configuring the spacer 6 into the column-like form using silica, resin and the like. The resultant spacers 61 are arranged on the inner surface 1a of the sealing substrate 1 via a bond member 10 as the bonding resin at the respective intervals so as to be fixed.

Meanwhile, in the embodiment shown in FIG. 7B, a spherical spacer 62 is derived by configuring the spacer 6 into the spherical (bead-like) form using silica, resin and the like. The resultant spacers 62 are arranged on the inner surface 1a of the sealing substrate 1 via the bond member 10 as the bonding resin at the respective intervals so as to be fixed.

The organic EL display device according to the third embodiment allows easy use of the spacer with the configuration and dimension which have been preliminarily set.

### Fourth Embodiment

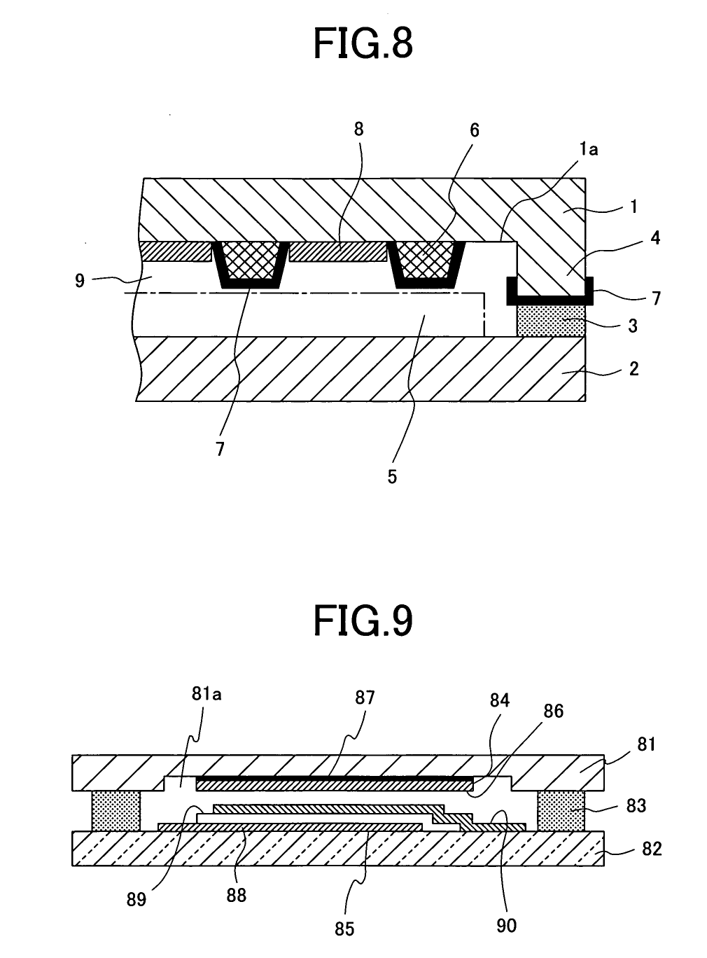

FIG. 8 is a sectional view schematically showing the structure of an organic EL display device according to another embodiment of the present invention. The same elements as those in the aforementioned embodiments will be designated with the same reference numerals. In the fourth embodiment, the side wall 4 is integrated with the sealing substrate 1 as shown in FIG. 8, and the surface of the side wall 4 bonded to the sealing member 3 is coated with the inorganic insulation film 7. The side wall 4 may be integrally formed with the sealing substrate 1, obtained by integrating separately formed flat plate and frame by heating, or formed through various processes. As the configuration of the side wall is relatively simple, it may be formed through etching for a short period of time.

The organic EL display device according to the fourth embodiment further reduces the path through which the moisture filtrates into the sealed space. In the aforementioned examples, the active type has been described. However, the present invention is applicable to the passive type.

What is claimed is:

1. An organic EL display device comprising:
a lower electrode disposed on a main surface of an element substrate;
an organic EL layer with a multi-layer structure disposed on the lower electrode;
an upper electrode disposed on the organic EL layer as an upper layer;
a sealing substrate disposed opposite the element substrate;
a plurality of spacers disposed between the sealing substrate and the element substrate; and
a sealing member for bonding a peripheral portion between the sealing substrate and the element substrate,
wherein the spacers are fixed to the sealing substrate, each surface of which is coated with an inorganic insulation film.

2. The organic EL display device according to claim 1, wherein the spacer is a resin shaped member.

3. The organic EL display device according to claim 1, wherein the spacer is fixed to the sealing substrate via a bond member which is different from a member for forming the spacer.

4. The organic EL display device according to claim 1, wherein the sealing substrate is provided with a side wall protruding toward the element substrate on the peripheral portion, and the inorganic insulation film is interposed between the side wall and the sealing member.

5. The organic EL display device according to claim 4, wherein the side wall is formed of the same material for forming the spacer, and is fixed to the sealing substrate via the sealing member.

6. The organic EL display device according to claim 1, wherein the sealing substrate includes the inorganic insulation film on an inner surface of an area enclosed by the side wall.

7. The organic EL display device according to claim 1, wherein the sealing substrate includes a desiccant at a portion opposite the upper electrode.

8. The organic EL display device according to claim 1, wherein the spacer protrudes from a surface of the desiccant toward the upper electrode.

9. The organic EL display device according to claim 1, wherein the organic EL layer includes an electron feed layer, a light emitting layer, a hole feed layer, and a hole implantation layer.

10. The organic EL display device according to claim 2, wherein the resin shaped member has a column-like form.

11. The organic EL display device according to claim 2, wherein the resin shaped member has a bead-like form.

12. An organic EL display device comprising:
a lower electrode disposed on a main surface of an element substrate;
an organic EL layer with a multi-layer structure disposed on the lower electrode;
an upper electrode disposed on the organic EL layer as an upper layer;
a sealing substrate disposed opposite the element substrate;
a plurality of spacers disposed between the sealing substrate and the element substrate; and
a sealing member for bonding a peripheral portion between the sealing substrate and the element substrate,
wherein the spacer is formed of a resist resin, and has a surface coated with an inorganic insulation film.

13. The organic EL display device according to claim 12, wherein the resist resin is formed of a photosensitive acrylic resin.

14. The organic EL display device according to claim 12, wherein a desiccant is coated on an area between the spacers.

15. The organic EL display device according to claim 12,
wherein the sealing substrate has a side wall protruding toward the element substrate on the peripheral portion;
the side wall is formed of the same material for forming the spacer; and
the inorganic insulation film is interposed between the side wall and the sealing member.
